(19) United States
(12) Patent Application Publication
(10) Pub. No.: US 2025/0169265 A1
(43) Pub. Date: May 22, 2025

(54) METHOD FOR SELECTIVE SURFACE ENGINEERING OF PEROVSKITE MICROWIRE ARRAYS

(71) Applicant: City University of Hong Kong, Hong Kong (HK)

(72) Inventors: Johnny Chung Yin HO, Hong Kong (HK); Dengji LI, Hong Kong (HK); You MENG, Hong Kong (HK); Yuxuan ZHANG, Hong Kong (HK)

(73) Assignee: City University of Hong Kong, Hong Kong (HK)

(21) Appl. No.: 18/513,810

(22) Filed: Nov. 20, 2023

(51) Int. Cl. H10K 30/10; H10K 30/87; H10K 85/50

(52) U.S. Cl. CPC H10K 30/10; H10K 30/87; H10K 85/50

(57) ABSTRACT

The surface of low-dimensional perovskites plays a crucial role in determining their intrinsic properties. Thus, specific surfaces may be designed to obtain a desired characteristic and/or a functional structure. Further, surface passivation could also be applied to stabilize and optimize the state-of-the-art perovskite-based optoelectronics. CsPbBr₃ microwires parallel arrays with specific (100)-terminated crystal planes were designed and fabricated to have excellent photodetection performance with long-term environment stability over 3000 hours. Further, environmental oxygen may be used to passivate the Br-vacancy-related trap states on the (100) surface and to create charge carrier nanochannels to enhance the (opto)electronic properties. The coupling effects between oxygen species and the specific terminated crystal planes of perovskites highlight the importance of surface engineering for designing and optimizing perovskite-based devices.

### FIELD

The present disclosure relates generally to photodetectors and perovskite microwire (MW) parallel arrays. More specifically, but not exclusively, the present disclosure concerns high-quality perovskite MW parallel arrays with specifically terminated (100) surfaces, methods of making the same, products including the same, methos of making said products, and uses thereof.

### BACKGROUND

The following discussion of the background art is intended to facilitate an understanding of the present disclosure only. It should be appreciated that the discussion is not an acknowledgement or admission that any of the material referred to was part of the common general knowledge as at the priority date of the application.

The surface of a material is an exposed terminated crystal plane, which dominates the physical and/or chemical properties of the micro- or nanoscale material. Thus, the optoelectronic performance of a semiconductor device may be significantly affected by manipulating the surface science of the material through specific surface engineering. Compared to the bulk crystal, the all-inorganic halide perovskites (HPs) micro/nanowires have been demonstrated to have excellent optoelectronic properties, which are attributable to their unique one-dimensional (1D) structure and contributions from surface engineering. Strategies to obtain one-dimensional HPs structures with desired morphology include capillary-bridge-manipulated graphoepitaxy and surface energy-mediated growth.

The optoelectronic performance and long-term stability of perovskites may be enhanced by surface passivation, especially with environmental gases, which have been shown to have a considerable regulatory effect on the optoelectronic properties of HPs surface. For instance, the surface passivation of perovskites with oxygen gas has been proposed to enhance light-emission efficiencies and spontaneous carrier recombination lifetimes, owing to the passivation to traps induced by bromine vacancies. However, the surface engineering and surface passivation on the specific surface of HPs and the corresponding differentiation effect are still unknown. For example, the role of crystal planes in determining the optoelectronic properties of perovskite, such as CsPbBr₃ perovskite, is unknown. There is lacking an in-depth understanding of the interaction between specific HPs surface and surrounding environmental gas. Thus, the extent to which current methods of surface manipulation may affect performance of IP devices is severely limited.

### SUMMARY

The present disclosure offers advantages, benefits, and other alternatives over known materials and methods, by providing high-quality perovskite microwire (MW) parallel arrays with specifically terminated surfaces, methods of making the same, products including the same, methos of making said products, and uses thereof.

In an aspect, provided is a high-quality perovskite MW parallel array, including perovskite; and oxygen-filled surface bromine vacancies; wherein the perovskite has specifically terminated surfaces. In an embodiment, the perovskite is an inorganic material. In another embodiment, the perovskite is a hybrid material including both an inorganic material and an organic material.

In an aspect, provided is a method of making a high-quality perovskite MW parallel array, including providing a substrate; growing perovskite MW parallel arrays on the substrate; and passivating with oxygen. In an embodiment, growing includes a chemical vapor deposition (CVD) step. In another embodiment, passivating with oxygen includes storing the perovskite MW parallel arrays in an ambient environment for about 3000 hours or more. In yet another embodiment, the substrate includes muscovite mica.

In an aspect, provided is a product including a high-quality MW parallel array. In an embodiment, the product is a photodetector. In another embodiment, the product is a sensor. In yet another embodiment, the product is an LED. In still another embodiment, the product is a synapse. In a further embodiment, the product is a memory device.

In an aspect, provided is a photodetector, including a high-quality perovskite MW parallel array and one or more electrodes; wherein the high-quality perovskite MW parallel includes perovskite and oxygen-filled surface bromine vacancies, wherein the perovskite has specifically terminated surfaces. In an embodiment, the perovskite is CsPbBr₃ and has specifically terminated (100) surfaces. In an embodiment, the perovskite is an inorganic material. In another embodiment, the perovskite is a hybrid material including both an inorganic material and an organic material. In yet another embodiment, the photodetector has an on/off ratio of about 3×10⁴ to about 5×10⁴. In still another embodiment, the photodetector has a responsivity of about 215 A W⁻¹ to about 263 A W⁻¹. In a further embodiment, the photodetector has a detectivity of about 0.86×10¹² to about 1.06×10¹² Jones. In yet a further embodiment, the photodetector has a rise of about 94 μs to about 200 μs. In still a further embodiment, the photodetector has a recovery time of less than about 300 μs. In an embodiment, the photodetector has an ambient stability of about 3000 or more hours.

In an aspect, provided is a method of making a photodetector, including providing a substrate; growing perovskite MW parallel arrays on the substrate; passivating the perovskite MW parallel arrays with oxygen; and depositing one or more electrodes onto the substrate.

### BRIEF DESCRIPTION OF THE FIGURES

Some embodiments of the present disclosure will become better understood when the following detailed description is read with reference to the accompanying figures, wherein:

FIG. 1A depicts atomic models of the major surfaces [(100), (110), and (111)] of CsPbBr₃, as determined by DFT calculations;

FIG. 1B depicts calculated PDOS results of the major surfaces [(100), (110), and (111)] of CsPbBr₃;

FIG. 1C is a schematic illustration of the surface band structure of the major surfaces [(100), (110), and (111)] of CsPbBr₃;

FIGS. 2A and 2B depict a schematic (2A) and an SEM image (2B) of an example CsPbBr₃ microwire(MW) arrays-based photodetectors;

FIG. 3A depicts a graph of the Log I-V curves of an example photodetector device;

FIG. 3B depicts a graph of the I-t curve of an example photodetector without and with 450 nm illumination of 0.1-30 mW cm⁻² power density, while the source-drain bias is 2 V;

FIG. 3C depicts a graph of the response and recovery times of an example photodetector device;

FIG. 3D depicts a graph of the normalized spectral response of an example device under the illumination of 400-600 nm wavelength;

FIG. 4A depicts a graph of the responsivity and detectivity versus power intensity of illumination of an example device;

FIG. 4B depicts a graph of the time-resolved response of an example initial device and the example device stored over 3000 h;

FIGS. 5A-5E depict graphs characterizing example CsPbBr₃ MW arrays-based photodetectors in different conditions: photoswitching curves recorded in air, vacuum, and pure oxygen, while source-drain bias and power density were regulated at 2V and 30 mW cm², respectively (FIG. 5A); photo-switching comparison curves in air and under vacuum for a constant measurement over 50 loops (FIG. 5B); high-resolution time-resolved photoswitching curves in air (FIG. 5C) and under vacuum (FIG. 5D); current-power density curve acquired in air and under vacuum (FIG. 5E);

FIGS. 6A-6F depict the characterization of and theoretical calculations on the (100) surface of perovskites; XPS spectra of Pb 4f_{5/2} and 4 f_{7/2} of the CsPbBr₃ MWs in oxygen and under vacuum (FIG. 6A); in-situ PL spectra of the as-grown MW sample with pure oxygen injection (FIG. 6B); 2D contour image of the in-situ PL spectra (FIG. 6C); PL decay dynamics of the sample in oxygen and under vacuum (FIG. 6D); current-voltage curve for the perovskite MWs device in vacuum (FIG. 6E) and air conditions (FIG. 6F);

FIGS. 7A-7E depicts theoretical models of the CsPbBr₃ surface with perfect (FIG. 7A), Br-vacancy (FIG. 7B) and oxygen-passivated vacancy (FIG. 7C); calculated energy band structures of intrinsic, Br-vacancy, and oxygen-passivated surfaces (FIG. 7D); calculated differential of charge density surrounding the passivated oxygen species (FIG. 7E); and

FIG. 8 depicts PDOS patterns of the intrinsic, Br-vacancy and O-passivated CsPbBr₃ (100) surfaces.

It should be appreciated that all combinations of the foregoing concepts and additional concepts discussed in greater detail below (provided such concepts are not mutually inconsistent) are contemplated as being part of the inventive subject matter disclosed herein and may be used to achieve the benefits and advantages described herein.

### DETAILED DESCRIPTION

The present disclosure provides a designed high-quality CsPbBr₃ microwire (MW) parallel array with specifically terminated (100) surfaces. Further, provided is a photodetector (PD) including the designed high-quality CsPbBr₃ MW parallel array with specifically terminated (100) surfaces, and the PD exhibits enhanced stability and optoelectronic performance. In addition, oxygen passivation enhanced PD performance by eliminating surface bromine vacancy (Br-vacancy), thereby significantly reducing nonradiative recombination. Moreover, the occupied oxygen species may form a fast transfer nanochannel for the charge carriers, thereby enhancing the photocurrent.

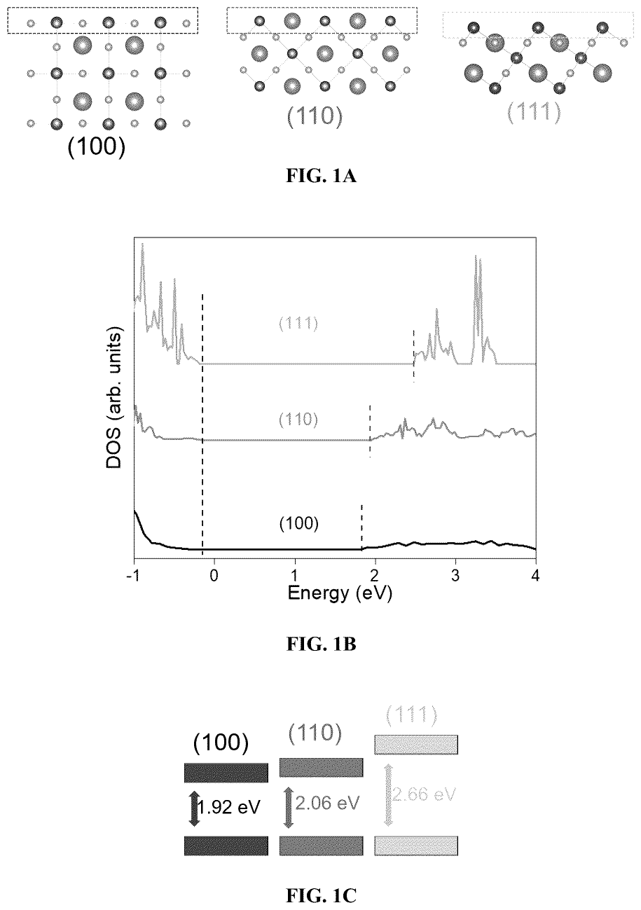

Now referring to FIGS. 1A-1C, theoretical simulations of DFT calculations demonstrate that the (100) surface of HPs structure possesses the lowest surface bandgap energy (1.92 eV) among all the surfaces of CsPbBr₃, inherently broadening the light-harvesting wavelength range.

The surface status of low-dimensional halide perovskites can determine their material property and device performance. For example, the (100) planes of HP crystals has been experimentally shown to exhibit higher carrier mobility and longer carrier lifetime than those of other terminated surfaces.

In an aspect, provided is a high-quality perovskite microwire (MW) parallel array, which may be designed and manufactured to have specifically terminated surfaces. In an example, the perovskite is CsPbBr₃. In another example, the (100) surfaces are specifically terminated. In yet another example, the perovskite is all-inorganic. Non-limiting examples of all-inorganic perovskites include CsPbCl3 and CsPbI3. In still another example, the perovskite is hybrid, e.g., both inorganic and organic. Non-limiting examples of hybrid perovskites include MAPbX₃, wherein X may be Cl, Br, or I. In a further example, the high-quality perovskite MW parallel array with specifically terminated (100) surfaces are manufactured by a process including chemical vapor deposition.

The present disclosure provides for designed and fabricated CsPbBr₃ microwires (MWs) parallel arrays with specific (100)-terminated crystal planes, and more notably, these selectively exposed (100) surfaces exhibit excellent photodetection performance together with long-term stability. The coupling effects between the surface attached species and the specific terminated perovskite planes highlight the importance of selective surface engineering for designing and optimizing perovskite-based devices in the future.

Surface passivation has been developed to enhance the optoelectronic performance and long-term stability of perovskites. Environmental gases are well known to have a considerable regulatory effect on the optoelectronic properties of HPs surface. For example, the surface passivation of perovskites with oxygen gas has been proposed to enhance light-emission efficiencies and spontaneous carrier recombination lifetimes, owing to the passivation to traps induced by bromine vacancies. However, the surface engineering and surface passivation on the specific surface of HPs and the corresponding differentiation effect are still unknown. An in-depth understanding of the interaction between specific HPs surface and surrounding environmental gas is essential for the further performance enhancement of HP devices.

In an aspect, provided is a high-quality perovskite microwire (MW) parallel array, wherein the high-quality perovskite MW parallel array is surface engineered to have specifically terminated surfaces. In an example, the perovskite is CsPbBr₃. In another example, the (100) surfaces are specifically terminated. In yet another example, the perovskite is all-inorganic. In still another example, the perovskite is hybrid, e.g., both inorganic and organic. In a further example, the high-quality perovskite MW parallel array with specifically terminated (100) surfaces is manufactured by a process including chemical vapor deposition.

In an aspect, provided is a method of making a high-quality perovskite microwire parallel array. In an example, high-quality single-crystalline CsPbBr₃ microwire parallel arrays may be synthesized on a substrate by chemical vapor deposition (CVD). Non-limiting examples of substrates include muscovite mica and sapphire. In an example, the substrate is muscovite mica. In another example, the substrate is sapphire. When the substrate is sapphire, the annealing temperature may be higher to pretreat the substrate.

The CVD process may be controlled to yield MW parallel arrays having a specific size and morphology. Non-limiting examples of CVD parameters that may be used to do so, include growth time, temperature, substrate location, and gas pressure within the chamber. In an example, the growth time is about 15 minutes to about 120 minutes, including all ranges, subranges, and values therein, e.g., about 15 minutes to about 105 minutes, about 30 minutes to about 90 minutes, about 45 minutes to about 75 minutes, about 30 minutes to about 60 minutes, about 60 minutes, etc. In an example, the first zone temperature is about 350° C. to about 550° C., including all ranges, subranges, and values therein, e.g., about 350° C. to about 400° C., about 400° C. to about 450° C., about 450° C. to about 500° C., about 500° C. to about 550° C., about 450° C. to about 500° C., about 480° C., etc. In an example, the second zone temperature is about 300° C. to about 330° C., including all ranges, subranges, and values therein, e.g., about 300° C. to about 310° C., about 310° C. to about 320° C., about 320° C. to about 330° C., about 310° C., etc. In an example the gas pressure is about 0.3 to about 2 Torr, including all ranges, subranges, and values therein, e.g., about 0.3 Torr to about 1 Torr, about 1 Torr to about 1.5 Torr, about 1. Torr to about 2 Torr, about 1. Torr, etc. In an example, the substrate is located about 10 cm to about 20 cm downstream of the center of the first zone, including all ranges, subranges, and values therein, e.g., about 10 cm to about 15 cm, about 15 cm to about 20 cm, about 12 cm to about 18 cm, about 12 cm to about 15 cm, about 15 cm, etc., downstream of the center of the first zone. In an example, the growth time is about 1 hour, the first zone temperature is about 480° C., the second zone temperature is about 310° C., the gas pressure is about 1.5 Torr, and the substrate is located about 15 cm downstream of the center of the first zone.

The PbBr₂ (99.999%) and CsBr (99.9%) powders were purchased from Sigma-Aldrich, and no extra purification operation was adopted. First, 100 mg of PbBr₂ powder and 70 mg of CsBr powder were fully ground in an agate mortar to form a yellow powder. The mixed powder was then pre-annealed at 370° C. for 30 mins, eventually forming orange powders. Then, a two-zone CVD system was adopted to realize the growth of CsPbBr₃ MW arrays. The mixed precursor powders were positioned in the center of 1st heating zone, and muscovite mica was located downstream (the 2nd heating zone), about 15 cm away from the source powder. Following, the entire system was evacuated to about 8 mTorr, and then 150 sccm high-purity Argon gas (Ar, 99.999%) was fed into the tube furnace to act as carrier gas. The flow rate was then manipulated to 100 sccm, and growth pressure was regulated to 1.5 Torr. After that, the 1st temperature zone was heated to 480° C. in 50 mins and held the temperature for 60 mins, while the 2nd temperature zone was held at 330° C. Eventually, an orange product was grown on the mica with the tube furnace cooling down to room temperature in the Ar atmosphere.

Non-limiting examples of a product include: a photodetector (PD), a sensor, a LED, a synapse, a memory device, etc. In an example, the product is a photodetector having an on/off ratio, a responsivity value, a detectivity value, a rise time, a recovery time, and an ambient stability time. The on/off ratio may be about 3×10⁴ to about 5×10⁴, including all ranges, subranges, and values therein, e.g., about 3×10⁴ to about 4×10⁴, about 4×10⁴ to about 5×10⁴, about 3×10⁴, about 4×10⁴, about 5×10⁴, etc. The responsivity value may be about 215 A W⁻¹ to about 275 A W⁻¹, including all ranges, subranges, and values therein, e.g., about 215 A W⁻¹ to about 235 A W⁻¹, about 235 A W⁻¹ to about 255 A W⁻¹, about 255 A W⁻¹ to about 275 A W⁻¹, about 263 A W⁻¹, etc. The detectivity value may be about 0.86×10¹² Jones to about 1.06×10¹² Jones, including all ranges, subranges, and values therein, e.g., about 0.86×10¹² Jones to about 0.96×10¹² Jones, about 0.96×10¹² Jones to about 1.06×10¹² Jones, about 1.06×10¹² Jones, etc. The rise time may be about 90 μs to about 200 μs, including all ranges, subranges, and values therein, e.g., about 90 μs to about 110 μs, about 110 μs to about 130 μs, about 130 μs to about 150 μs, about 150 μs to about 170 μs, about 170 μs to about 190 μs, about 190 μs to about 200 μs, about 94 μs, etc. The recovery time may be less than about 300 μs, including all ranges, subranges, and values therein, e.g., about 136 μs, about 130 μs to about 160 μs, about 160 μs to about 190 μs, about 190 μs to about 220 μs, about 220 μs to about 250 μs, about 250 μs to about 280 μs, about 280 μs to about 300 μs, etc. The ambient stability time may be more than about 3000 hours, including all ranges, subranges, and values therein, e.g., about 3000 hours, about 2 years, etc.

In an example, the photodetector has an on/off ratio of 5×10⁴, a responsivity of 263 A W⁻¹, a detectivity of 1.06×10¹² Jones, a rise of 94 μs, a recovery time of 136 μs, and an ambient stability of 3000 hours.

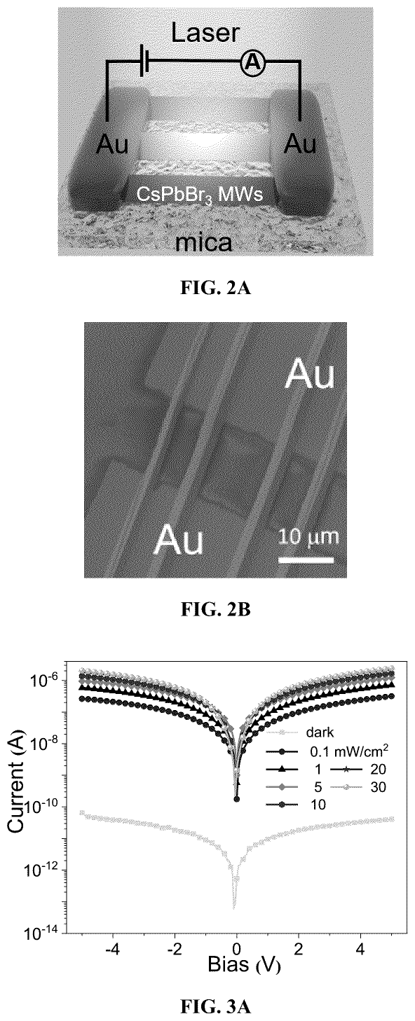

Now referring to FIGS. 2A and 2B, in an example, the (100) surface-engineered structures of perovskite MW arrays were configured into a PD structure (FIG. 2A). Specifically, after the perovskite MW arrays were grown on the mica substrate, 50 nm thick Au electrodes were thermally evaporated on the substrate through a shadow mask with a channel length of 15 m. The SEM image of the PD structure is provided in FIG. 2B, which supports that these triangular prism MWs have smooth and flat surfaces with perfect horizontal alignments lying on the substrates. The high-quality surface condition of the MWs contributes to the good optoelectronic performance of devices that include the MWs.

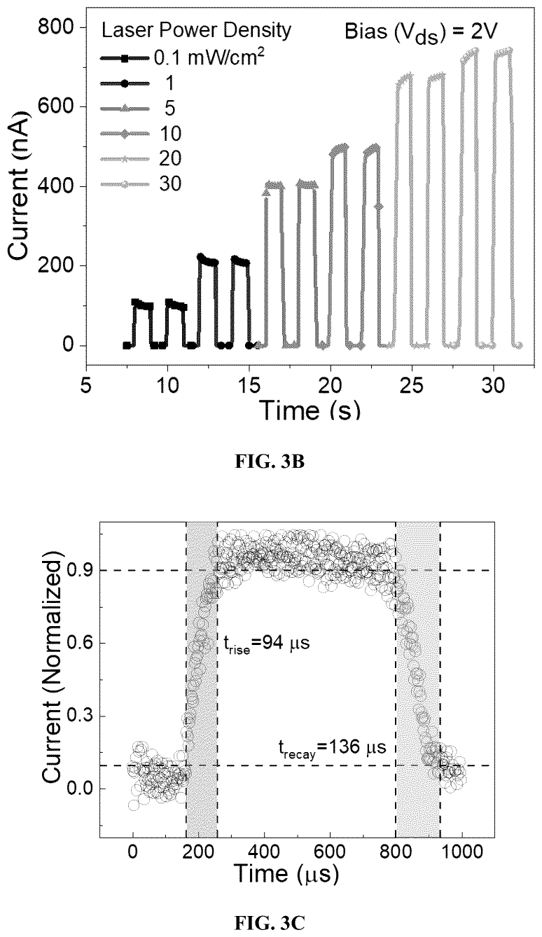

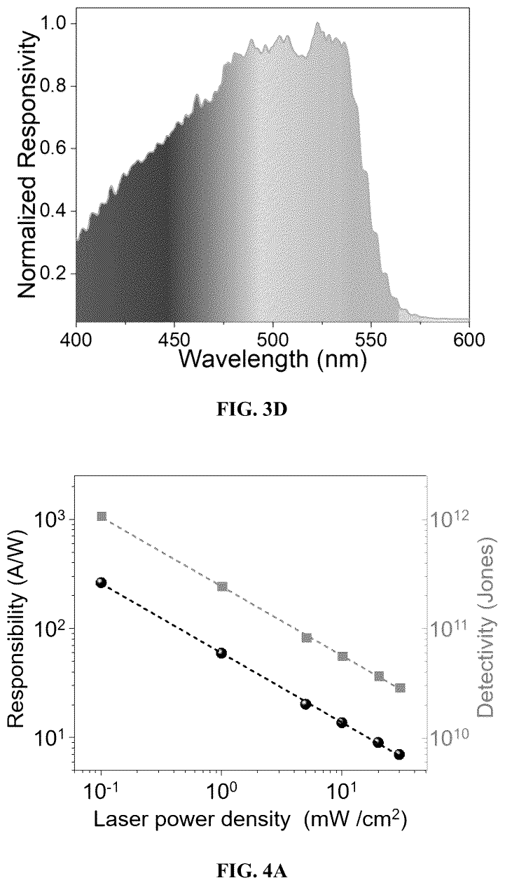

Now referring to FIGS. 3A-3D, the corresponding current-voltage (I-V) curve was acquired in the dark and under different power intensities (0.1 to 30 mW cm⁻²) (FIG. 3A). When the 450 nm light was irradiated on the (100) surface, the photogenerated carriers were effectively separated and transported through the perovskite MWs. These results demonstrate that the photocurrent increased with power intensity, indicating that more photogenerated carriers were created under the 450 nm source with increasing power intensity. This can be explained by the fact that increasing the power intensity leads to a greater number of photons interacting with the electrons, resulting in more electrons acquiring energy from the photons and transitioning from the valence band to the conduction band. These (100) surface-based devices exhibited a dark current as low as 15 pA, whereas the output current enhanced by 4.5 orders of magnitude to above 800 nA under 30 mW cm⁻² illumination. The on-off switching characteristics (FIG. 3B) demonstrate that the photocurrent tended to increase as the power intensity increased, which is consistent with the theory that the quantity of photogenerated carriers is proportional to the arriving photon flux. To acquire the precise response and recovery times of the devices, the on-off switching measurement was manipulated by a high-frequency chopper, while a digital oscilloscope recorded the temporal response. The response (purple) and recovery (blue) times, recognized as the time for the photocurrent to shift from 10% to 90% and from 90% to 10% of the maximum output signal, were found to be 94 μs and 136 μs, respectively (FIG. 3E). These results are faster than those of the previous photodetector devices based on perovskite nano/microwires arrays or films (see Table 1, below).

The device was continuously irradiated with wavelength changing from 400 to 600 nm. The responsivity of the MW photodetector reached a peak at around 500 to 550 nm and then declined sharply at about 560 nm (FIG. 2F).

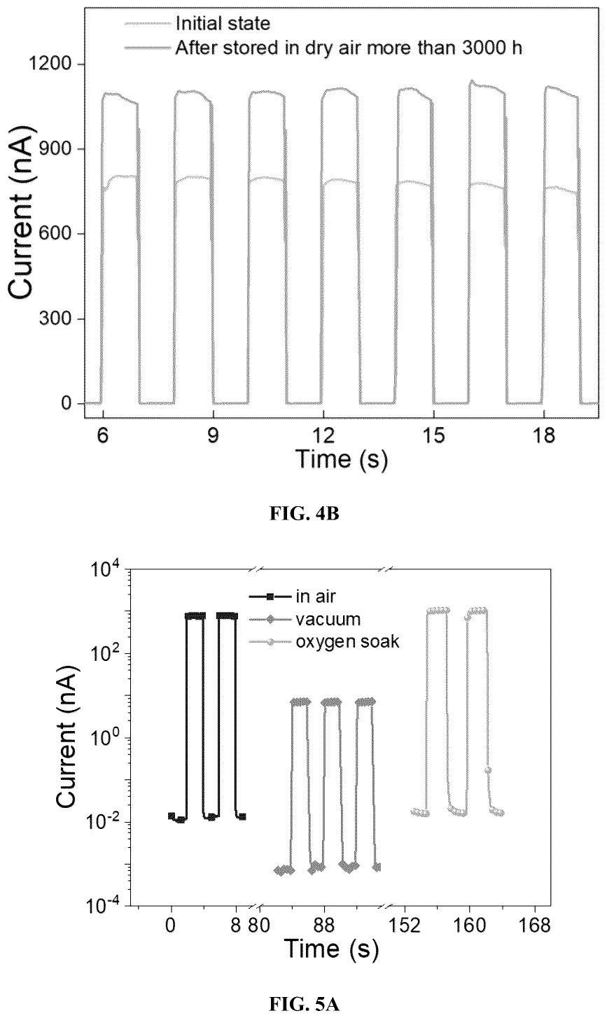

Now referring to FIGS. 4A and 4B, to evaluate the performance of PD devices, there are two important figures of merit parameters, namely responsivity (R) and detectivity (D*), which can be directly extracted from the measurement results. The mathematical expression of R is described by the equation of R Iₚₕ/PS, where Iₚₕ (Iₚₕ=I_{light}−I_{dark}). Iₚₕ, P, and S are the photocurrent, incident power density illuminated on the MW array, and effective illumination area on the MW arrays, respectively. Meanwhile, another parameter, D*, is defined as D*=R(S Δf)^{1/2}/iₙ, where iₙ is the noise current. FIG. 4A shows the calculated R and D* under different power densities, revealing both R and D* tend to decrease with increasing power density. These decay trends in R and D* were speculated to be caused by the trap states within the CsPbBr₃ MW body or at the surface of perovskite MWs. At a relatively low light power intensity (0.1 mW cm⁻²), the device reached a high photoresponsivity of 263 A W⁻¹ and a good detectivity of 1.06×10¹² Jones. At the same time, long-term stability is always regarded as a stumbling block for the practical and commercial development of perovskite-based photodetectors. As illustrated in FIG. 4B, the photocurrent of the perovskites MW arrays device gets enhanced to 140% of its initial value after being stored in an ambient environment for 3000 hours, demonstrating excellent resistance to the external environmental stimulus.

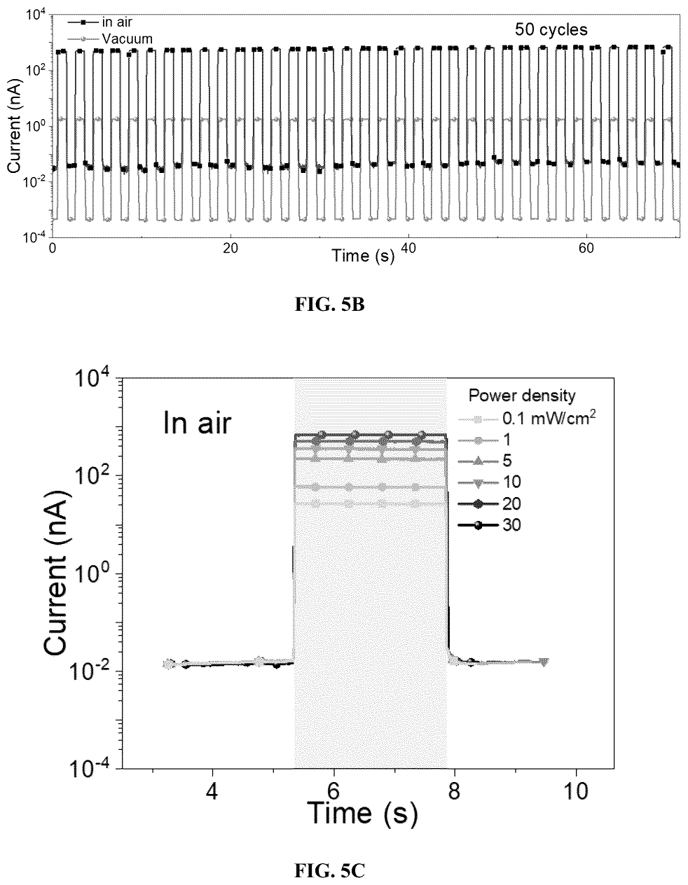

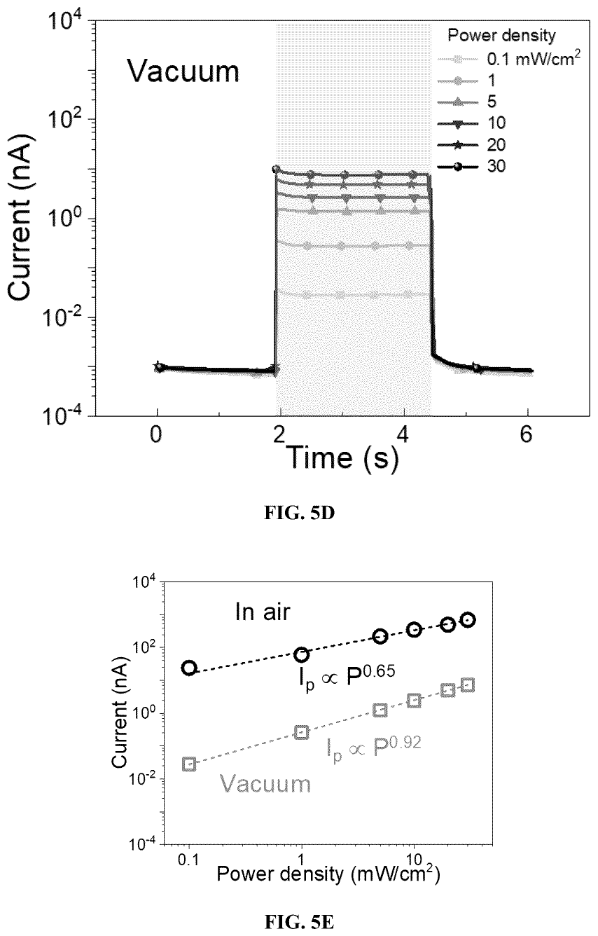

Now referring to FIGS. 5A-5E, a comparison experiment was designed to assess the detection performance of the devices in air, vacuum, and pure oxygen environment, respectively. The device exhibited a similar photocurrent under 30 mW cm⁻² power density illumination in air and pure oxygen environment but a remarkable photocurrent decline (about two orders) in the vacuum condition (˜10⁻⁴ Pa) (FIG. 5A). To eliminate the influence of oxygen species, the vacuuming process was maintained for at least 36 hours before measurement.

The short-term stability of devices in air and vacuum environment was also investigated. The photo- and dark-current were measured under several photo-switching cycles, demonstrating again their operational stability (FIG. 5B). To further explore the physical nature of oxygen impact on the detection characteristics, the device was measured under different power density (from 0.1 to 30 mWcm⁻²) illumination both in air and under vacuum (FIGS. 5C and 5D), with the photocurrent for each condition extracted and compiled in FIG. 5E. It is evident that all the experimental data is well-fitted by the power law equation of Iₚₕ∝P^{a}. The extracted a values in air and under vacuum were calculated to be 0.65 and 0.92, respectively, which reveals the different optoelectronic properties of (100) surface under those two conditions (i.e., air versus vacuum).

### EXAMPLES

In an aspect, provided is a method of manufacturing a photodetector, including growing perovskite MW parallel arrays on a substrate and evaporating Au onto the perovskite MW parallel arrays, wherein the perovskite MW parallel array is surface engineered to have a specific terminated surface to enhance performance.

A direct evaporation scheme was utilized to fabricate the photodetectors. To fabricate the device, perovskite MW parallel arrays were grown on a mica substrate. Next, 50 nm thick Au (99.99%) electrodes were thermally evaporated onto the samples by utilizing a nickel shadow mask with channel length of 15 μm. This deposition was conducted at a deposition rate of roughly 2 Å/s under high vacuum, where the thickness of the Au electrodes was directly proportional to the deposition time that was monitored by a quartz crystal. Based on the specific terminated crystal planes of the CsPbBr₃ MW arrays, the effective area was calculated considering the two perpendicular planes, (100) and (010). The efficient area (S) was calculated as the projection area of these two planes on substrates, S=L×2W×N, where L, W, and N represent channel length, channel width, and the number of MWs, respectively. A standard electrical probe station equipped with the semiconductor analyzer Agilent 4155C was adopted to measure the optoelectronic properties of perovskite MW arrays in the ambient environment, while a high vacuum probe station was used to measure the optoelectronic performance under vacuum. A 450 nm wavelength laser diode was employed to provide the illumination, of which the power density was measured by a PM400 power meter (Thorlabs). The high-precision photo response was realized by a high-frequency chopper and recorded by TBS 1102B-EDU digital oscilloscope (Tektronix) connected with a SR570 current preamplifier (Stanford Research Systems).

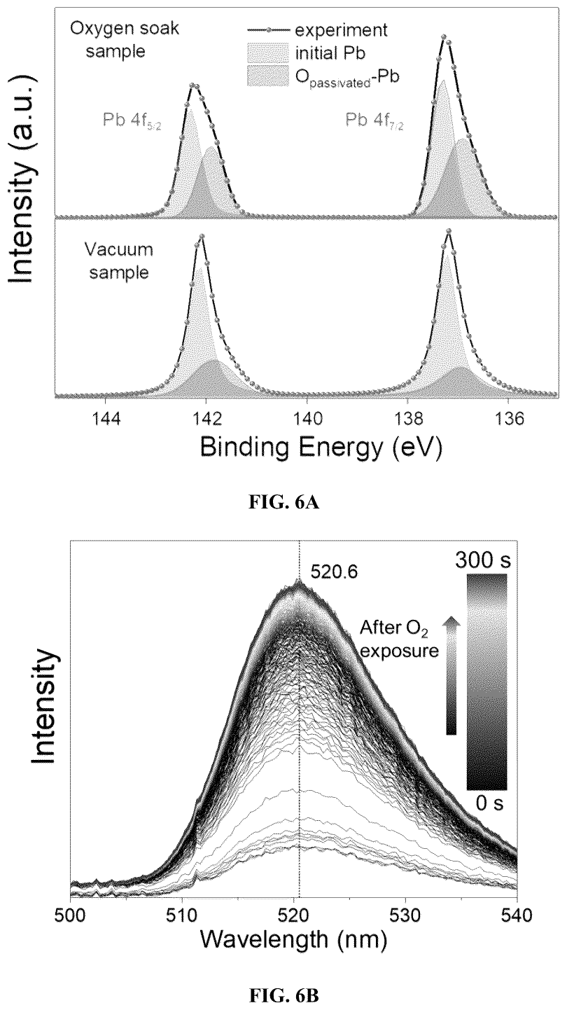

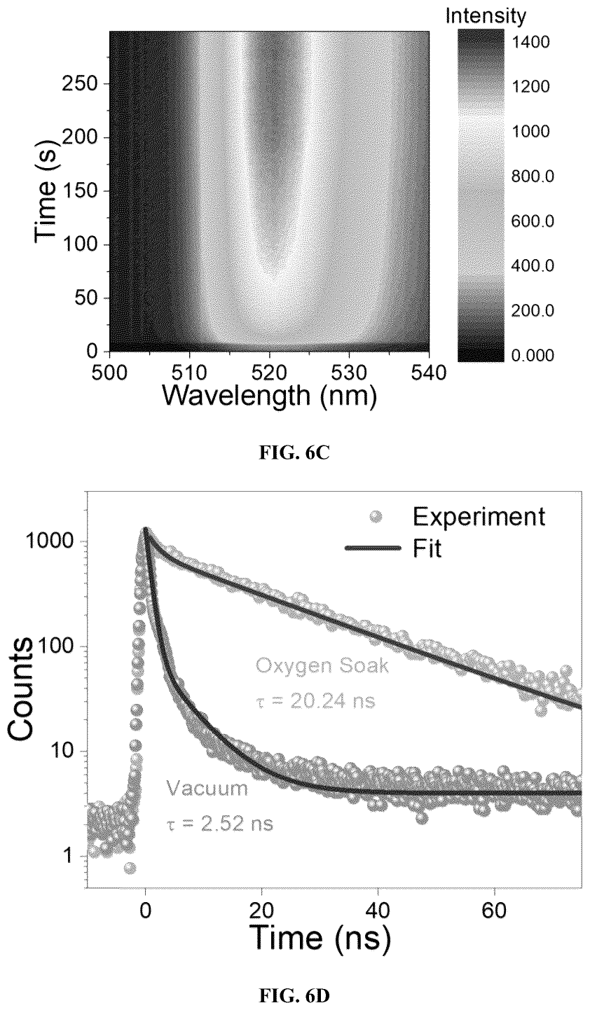

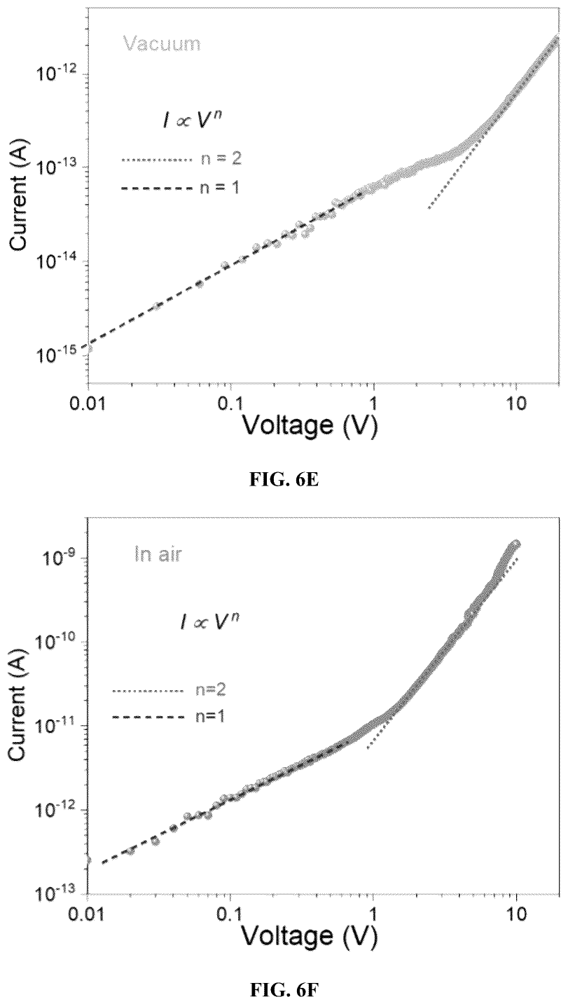

Now referring to FIGS. 6A-6F, X-ray photoelectron spectroscopy (XPS) was performed to assess the interaction between the oxygen species and perovskite MW arrays. The corresponding XPS results under different environments are shown in FIG. 6A. For the (100) surface terminated CsPbBr₃ MW arrays measured in the oxygen environment, the peaks at 137.3 eV and 142.3 eV corresponded to Pb 4f_{7/2} and Pb 4f_{5/2}, respectively. The broadened peak could be divided into two additional lower binding energy peaks at 136.9 eV and 141.9 eV, which could be assigned to the oxygen passivation effect. Accordingly, as the surrounding environment was pumped down to vacuum, the peaks of 4f_{7/2} and Pb 4f_{5/2} became narrower and sharper, whereas the peaks representing the oxygen passivation effect were close to vanishing. The XPS findings support the existence of oxygen on the (100) surface of all-inorganic CsPbBr₃ MW arrays in the ambient environment.

An in-situ PL spectroscopic study was carried out in a high vacuum condition as well as in an oxygen environment to determine the oxygen passivation effect on the carrier recombination pathways. The PL intensity of the CsPbBr₃-characteristic peak at 520.6 nm enhanced over time after introducing pure oxygen to the chamber (FIG. 6B). As the system was evacuated to vacuum, the peak intensity could recover to its initial state. The visualization of the tracked PL spectrum during the transfer from vacuum to oxygen environments is shown in FIG. 6C and indicates the enhanced intensity of the maintained characteristic peak. This supports the passivation effect of oxygen species to the (100) surface of perovskite MW arrays. This PL intensity switching response caused by oxygen passivation is the characteristic effect of the surface Br-vacancy type perovskite, signifying the dominant Br-vacancy defects on the (100) surface of CsPbBr₃ MW arrays.

The double-exponential fitting curve was adopted to fit the time-resolved PL (TRPL) decay results in order to analyze the PL recombination dynamics of the perovskite MWs in different conditions (FIG. 6D). In vacuum conditions, the extracted fast and slow components of PL lifetimes, τ₁ and τ₂, were determined to be 0.87 ns and 5.96 ns, respectively, which increased to 1.86 ns and 21.2 ns after oxygen injection. At the same time, the average lifetime, τ, can be estimated by an equation of τ=ΣᵢAᵢτᵢ²/ΣᵢAᵢτᵢ. This way, the average lifetime, τ, was calculated to be 2.52 ns and 20.24 ns for vacuum and oxygen conditions, respectively. This increasing trend of PL lifetime caused by oxygen passivation indicates that the nonradiative recombination is suppressed owing to the reduced defect density passivated by oxygen species, being consistent with the enhancing fluorescence intensity due to the oxygen species passivation to traps. Additionally, to evaluate the defect density, a detailed analysis of the SCLC results is shown in FIGS. 6E and 6F. The trap density (nₜ) can be determined by trap-filled limit voltage (V_{TFL}),

$${V}_{T F L} = \frac{e {n}_{t} {L}^{2}}{2 ε {ε}_{0}}$$

where L is the channel length, ε(19.2) is relative dielectric constant of CsPbBr₃ and ε₀ is the vacuum permittivity. Hence, the trap density nₜ of CsPbBr₃ in air was calculated to be 1.05×10¹⁴ cm⁻³, which is lower than that in vacuum (4.68×10¹⁴ cm⁻³), indicating a fewer trap density in air condition. These results demonstrate the effectiveness of the oxygen passivation strategy disclosed herein, in reducing the trap density and improving the optoelectronic performance of the (100) surface of perovskite MW arrays.

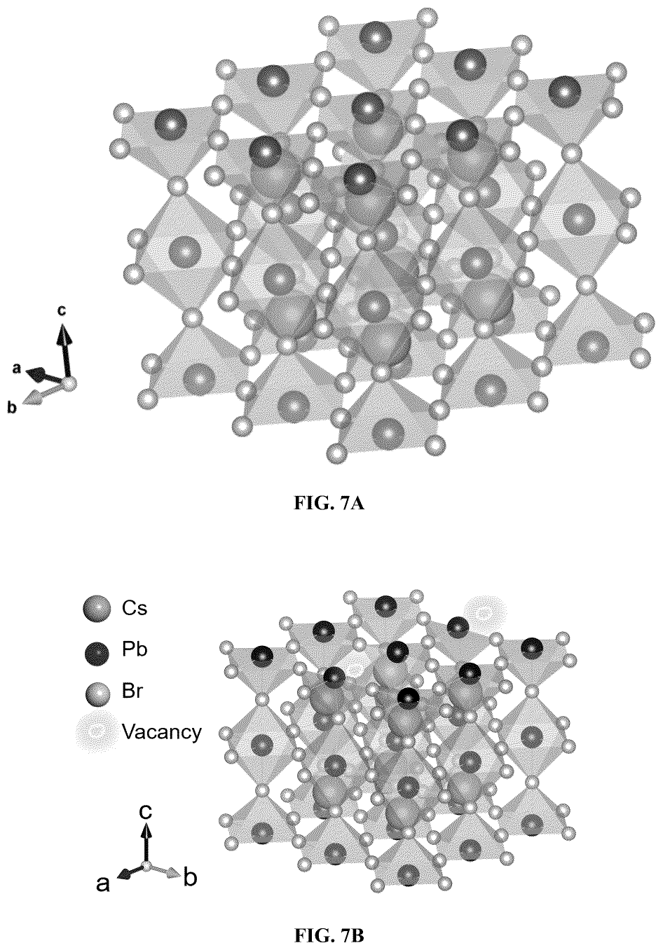

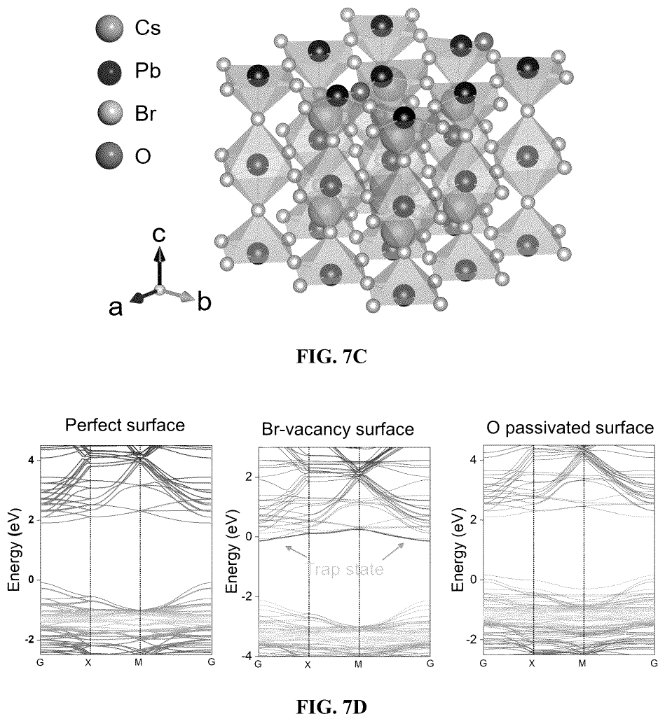

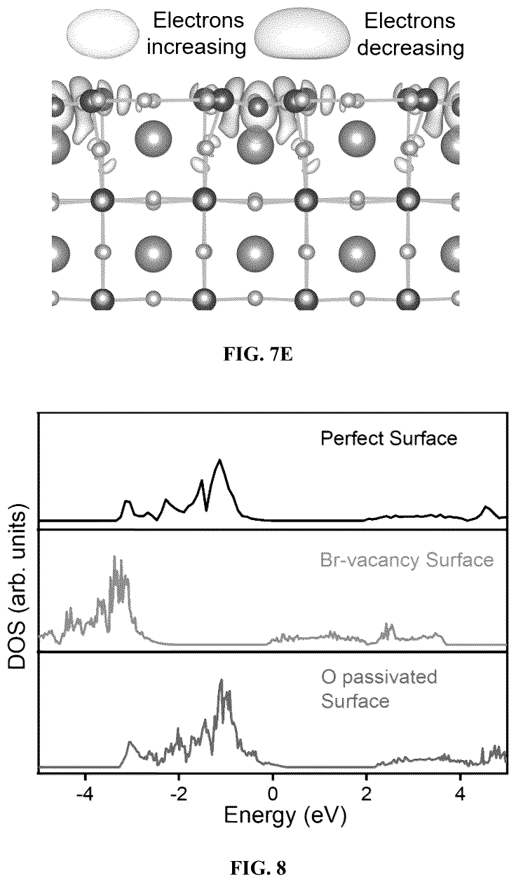

Now referring to FIGS. 7A-7E, first-principal density functional theory (DFT) simulations were conducted to thoroughly understand the passivation mechanism of these oxygen species on perovskites. Simultaneously, the perfect CsPbBr₃ surface model was built for reference and is shown in FIG. 7A. The (100) surface of cubic CsPbBr₃ with Br vacancies and vacancies passivated by oxygen species are modeled in FIGS. 7B and 7C, respectively. To investigate the specific passivation effect of oxygen species passivation to the Br-vacancy, the band structures of these three models were calculated, and the corresponding results are displayed in FIG. 7D. For the Br-vacancy surface, several distinct additional energy levels mainly originated from the p-orbital of Pb were beneath the conduction band (CB) edge, which was considered the trap states. These detrimental trap states act as the center of nonradiative recombination, leading to the capture of photogenerated carriers and a shorter diffusion length, hence deteriorating the optoelectronic performance of the device.

With those vacancies occupied by oxygen species, these detrimental trap levels vanished in the energy band, while the entire energy band structure was similar to the intrinsic CsPbBr₃. The corresponding partial density of state (PDOS) results are shown in FIG. 8, illustrating more details of the energy band structures. Besides, the differential charge density of the oxygen-passivated (100) surface to the Br-vacancy surface was calculated, and the corresponding result is shown in FIG. 4H. Distinct fast charge transfer nanochannels are formed surrounding the oxygen species, beneficial to the rapid transfer of the charge carriers. Hence, these results indicate that the oxygen passivation can not only optimize the energy band and eliminate the trap states but also generate charge carries nanochannels for realizing the photocurrent enhancement, agreeing well with the experimental findings.

TABLE 1
A comparison of the performance of photodetectors based on the perovskite NWs/MW network/arrays or films.

| | | | | | Stored | Maintain | Time | Time | |
|---|---|---|---|---|---|---|---|---|---|
| | | On/Off | R | D*(*10¹²) | time | performance | Rising | Recovery | |
| Materials | morphology | ratio | (A/W) | Jones | (h) | (%) | (μs) | (μs) | Reference |
| CH₃NH₃PbI₃ | Network | 300 | 0.13 | 1.02 | 720 | 70 | 300 | 400 | ^{[1]} |
| CH₃NH₃PbI₃/ | Network | 9750 | 8.1 | 2.17 | 1200 | 70 | 7100 | 6500 | ^{[2]} |
| C8BTBT | | | | | | | | | |
| CH₃NH₃PbI₃ | MW arrays | 134 | 13.57 | 5.25 | 1200 | 90 | 80 | 240 | ^{[3]} |
| CH₃NH₃PbI₃ | NWs | 300 | 460 | 26 | 1080 | 80 | 180 | 330 | ^{[4]} |
| CH₃NH₃PbI₃ | Film | 60 | 0.418 | 12.2 | 240 | 40 | 80000 | 80000 | ^{[5]} |
| CH₃NH₃PbI₃/ | Film | — | 0.0107 | 0.0061 | 336 | 90 | — | — | ^{[6]} |
| PDPP3T | | | | | | | | | |
| CH₃NH₃PbI₃ₓ | NWs | 100 | 0.62 | 7.3 | 720 | 95 | 227.2 | 214.5 | ^{[7]} |
| (SCN)ₓ/PMMA | | | | | | | | | |
| CH₃NH₃PbI₃ | MW arrays | 1000 | 0.48 | 1.26 | 48 | 83 | 36000 | 43000 | ^{[8]} |
| CH₃NH₃PbI₃ | MW | 20000 | 13.8 | 2.55 | 2160 | 95 | 50000 | 50000 | ^{[9]} |
| CH₃NH₃SnI₃ | NW | 10 | 0.47 | 0.088 | 168 | 13.6 | 1.5 × 10⁶ | 4 × 10⁵ | ^{[10]} |
| In₂S₃/Al₂O₃/ | dot | 10⁶ | 2812 | 2000 | 720 | 105 | 144 | 32 | ^{[11]} |
| CsPbBr₃ | | | | | | | | | |
| CsPbBr₃ | Film | 2.6 × 10⁵ | 0.4 | 7.01 | 1344 | 93 | 10 | 27 | ^{[12]} |
| CsPbBr₃ | Film | 3.5 × 10⁴ | — | 0.44 | 1000 | 97 | 3.8 | 4.6 | ^{[13]} |
| CsPbBr₃ | Film | 10³ | 0.44 | 18.8 | 2400 | 96 | 28 | 270 | ^{[14]} |
| CsPbBr₃ | MWs | >10³ | 0.001 | ~0.01 | — | — | 105 | 105 | ^{[15]} |
| CsPbBr₃ | MWs | >100 | 118 | 1 | — | — | 40000 | 40000 | ^{[16]} |
| CsPbBr₃ | NWs | 10 | 6.44 | 2.88 | — | — | 3 × 10⁵ | 2.4 × 10⁵ | ^{[17]} |
| CsPbBr₃ | NWs | >10³ | 7.66 | 4.05 | — | — | 2.8 × 10⁵ | 5.5 × 10⁵ | ^{[18]} |
| C8/CsPbBr₃ | NWs | 2.957 × 10³ | 2.4 × 10⁻³ | 6.17 | — | — | 3000 | 2800 | ^{[19]} |
| Cs₃Sb₂Cl₉ | NWs | 10 | 3616 | 1.2 × 10⁻⁶ | — | — | 1.3 × 10⁵ | 2.3 × 10⁵ | ^{[20]} |
| CsSnI₃ | MW arrays | 1.08 | 54 | 3.85 × 10⁻⁷ | — | — | 83800 | 2.4 × 10⁵ | ^{[21]} |
| CsPbₓSn₁₋ₓBr₃ | NWs | 80 | 0.011 | 0.02 | — | — | 4250 | 4820 | ^{[22]} |
| CsPbBr₃ | MW arrays | 5 × 10⁴ | 263 | 1.06 | 3000 | 138 | 94 | 136 | here |

NWs = nanowire; MWs = microwires.

### DFT Calculation

In this study, the Vienna Ab-initio Simulation Package (VASP) was adopted to perform the corresponding density functional theoretical (DFT) calculation for different models.[²³] More specifically, these DFT calculations were carried out through the Perdew-Burke-Ernzerhof (PBE) functional within generalized gradient approximation (GGA).[²⁴] The surfaces of all models were modeled as a 2D cubic slab with (001) surface exposure. The slab was designed as a 2-layers system including 125 atoms supercell of the optimized cubic structure (a=b=c=5.8 Å). Here, the vacuum gap was set as 30 Å, while 450 eV was chosen for the energy cutoff of the plane-wave expansion. Besides, a convergence criterion of 10⁻⁴ eV was set for total energy and the structure was regulated to be relaxed until the maximum stress on each atom is lower than 0.03 eV/Å. At last, the Γ-centered k-point mesh of 5×5×1 and 7×7×1 is adopted for structural relaxation and DOS calculation, respectively.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), “contain” (and any form contain, such as “contains” and “containing”), and any other grammatical variant thereof, are open-ended linking verbs. As a result, a method or article that “comprises”, “has”, “includes” or “contains” one or more steps or elements possesses those one or more steps or elements, but is not limited to possessing only those one or more steps or elements. Likewise, a step of a method or an element of an article that “comprises”, “has”, “includes” or “contains” one or more features possesses those one or more features, but is not limited to possessing only those one or more features.

Terms like “obtainable” or “definable” and “obtained” or “defined” are used interchangeably. This, for example, means that, unless the context clearly dictates otherwise, the term “obtained” does not mean to indicate that, for example, an embodiment must be obtained by, for example, the sequence of steps following the term “obtained” though such a limited understanding is always included by the terms “obtained” or “defined” as a preferred embodiment.

Approximating language, as used herein throughout disclosure, may be applied to modify any quantitative representation that could permissibly vary without resulting in a change in the basic function to which it is related. Accordingly, a value modified by a term or terms, such as “about” or “substantially,” is not limited to the precise value specified. For example, these terms can refer to an amount that is within ±10% of the recited value, an amount that is within ±5% of the recited value, less than or equal to ±2%, an amount that is within ±1% of the recited value, an amount that is within ±0.5% of the recited value, an amount that is within ±0.2% of the recited value, an amount that is within ±0.1% of the recited value, or an amount that is within ±0.05% of the recited value. In some instances, the approximating language may correspond to the precision of an instrument for measuring the value.

All publications cited in this specification are herein incorporated by reference as if each individual publication were specifically and individually indicated to be incorporated by reference herein as though fully set forth.

Subject matter incorporated by reference is not considered to be an alternative to any claim limitations, unless otherwise explicitly indicated.

Where one or more ranges are referred to throughout this specification, each range is intended to be a shorthand format for presenting information, where the range is understood to encompass each discrete point within the range as if the same were fully set forth herein.

While several aspects and embodiments of the present disclosure have been described and depicted herein, alternative aspects and embodiments may be affected by persons having ordinary skill in the art to accomplish the same objectives. Accordingly, this disclosure and the appended claims are intended to cover all such further and alternative aspects and embodiments as fall within the true spirit and scope of the present disclosure.

The following references are incorporated in their entireties and a skilled person is considered to be aware of disclosure of these references.
[1]J. Xue, R. Wang, Y Yang, Nat. Rev. Mater, 2020, 809.
[2]W. Shockley, Physical review, 1939, 56, 317; S. G. Davison, M. Steslicka, Basic theory of surface states, Vol. 46, Oxford University Press, 1996.
[3]R. Wang, J. Xue, K.-L. Wang, Z.-K. Wang, Y Luo, D. Fenning, G. Xu, S. Nuryyeva, T. Huang, Y Zhao, Science 2019, 366, 1509; H. Min. M. Kim, S.-U. Lee, H. Kim, G. Kim, K. Choi, J. H. Lee, S. I. Seok, Science 2019, 366, 749; Y-H. Kim, S. Kim, A. Kakekhani, J. Park, J. Park, Y-H. Lee, H. Xu, S. Nagane, R. B. Wexler, D.-H. Kim, Nat. Photonics 2021, 15, 148; Y Zhao, Y Qiu, J. Feng, J. Zhao, G. Chen, H. Gao, Y Zhao, L. Jiang, Y Wu, J. Am. Chem. Soc. 2021, 143, 8437; Y Zhao, Y Qiu, H. Gao, J. Feng, G. Chen, L. Jiang, Y Wu, Adv. Mater 2020, 32, 1905298.
[4]J. D. Jackson, Classical electrodynamics, John Wiley & Sons, 2021; Y Wang, X. Sun, R. Shivanna, Y Yang, Z. Chen, Y Guo, G.-C. Wang, E. Wertz, F. Deschler, Z. Cai, Nano Lett. 2016, 16, 7974.
[5]S. Dong, Z. Y Hu, P. Wei, J. Han, Z. Wang, J. Liu, B. L. Su, D. Zhao, Y Liu, Adv. Mater. 2022, 34, 2204342
[6]H. Deng, X. Yang, D. Dong, B. Li, D. Yang, S. Yuan, K. Qiao, Y-B. Cheng, J. Tang, H. Song, Nano Lett. 2015, 15, 7963; I. M. Asuo, D. Gedamu, I. Ka, L. F. Gerlein, F.-X. Fortier, A. Pignolet, S. G. Cloutier, R. Nechache, Nano Energy 2018, 51, 324
[7]H.-H. Fang, S. Adjokatse, H. Wei, J. Yang, G. R. Blake, J. Huang, J. Even, M. A. Loi, Sci. Adv. 2016, 2, e1600534.
[8]D. Lu, Y Zhang, M. Lai, A. Lee, C. Xie, J. Lin, T. Lei, Z. Lin, C. S. Kley, J. Huang, Nano Lett. 2018, 18, 6967; Y Wang, Y Ren, S. Zhang, J. Wu, J. Song, X. Li, J. Xu, C. H. Sow, H. Zeng, H. Sun, Commun. Phys. 2018, 1, 1.
[9]M. Shoaib, X. Zhang, X. Wang, H. Zhou, T. Xu, X. Wang, X. Hu, H. Liu, X. Fan, W. Zheng, J. Am. Chem. Soc. 2017, 139, 15592.
[10]D. Li, Y Meng, Y Zheng, P. Xie, X. Kang, Z. Lai, X. Bu, W. Wang, W. Wang, F. Chen, Adv. Electron. Mater. 2022, 2200727.
[11]Y Fu, M. Yuan, Y Zhao, M. Dong, Y Guo, K. Wang, C. Jin, J. Feng, Y Wu, L. Jiang, Adv. Funct. Mater. 2023, 2214094.
[12]J. Chen, Y Fu, L. Samad, L. Dang, Y Zhao, S. Shen, L. Guo, S. Jin, Nano Lett. 2017, 17, 460.
[13]X. Mo, X. Li, G. Dai, P. He, J. Sun, H. Huang, J. Yang, Nanoscale 2019, 11, 21386; C. Fan, K. Bi, Z. Shu, X. Xu, B. Dai, S. Wang, Z. Qi, J. Wei, H. Duan, Q. Zhang, J. Phys. D: Appl. Phys. 2020, 53, 235105.
[14]W. Wang, Y Meng, W. Wang, Z. Zhang, P. Xie, Z. Lai, X. Bu, Y Li, C. Liu, Z. Yang, Adv. Funct. Mater. 2022, 2203003.
[15]J.-H. Kim, M. R. Bergren, J. C. Park, S. Adhikari, M. Lorke, T. Frauenheim, D.-H. Choe, B. Kim, H. Choi, T. Gregorkiewicz, Nat. Commun. 2019, 10, 1.
[16]O. Lopez-Sanchez, D. Lembke, M. Kayci, A. Radenovic, A. Kis, Nat. Nanotechnol. 2013, 8, 497.
[17]D. N. Dirin, I. Cherniukh, S. Yakunin, Y Shynkarenko, M. V. Kovalenko, Chem. Mater. 2016, 28, 8470.
[18]C. Lan, R. Dong, Z. Zhou, L. Shu, D. Li, S. Yip, J. C. Ho, Adv. Mater. 2017, 29, 1702759; Y Lee, D. Yoon, S. Yu, H. Sim, Y Park, Y S. Nam, K. J. Kim, S. Y Choi, Y Kang, J. Son, Adv. Mater. 2022, 34, 2107650.
[19]S.-C. Liu, Z. Li, Y Yang, X. Wang, Y-X. Chen, D.-J. Xue, J.-S. Hu, J. Am. Chem. Soc. 2019, 141, 18075; W. Fan, Y Shi, T. Shi, S. Chu, W. Chen, K. O. Ighodalo, J. Zhao, X. Li, Z. Xiao, ACS Energy Lett. 2019, 4, 2052.
[20]Y Wang, Z. Lv, J. Chen, Z. Wang, Y Zhou, L. Zhou, X. Chen, S. T. Han, Adv. Mater. 2018, 30, 1802883; Z. Lv, M. Chen, F. Qian, V. A. Roy, W. Ye, D. She, Y Wang, Z. X. Xu, Y Zhou, S. T. Han, Adv. Funct. Mater. 2019, 29, 1902374.
[21]M. Lorenzon, L. Sortino, Q. Akkerman, S. Accornero, J. Pedrini, M. Prato, V. Pinchetti, F. Meinardi, L. Manna, S. Brovelli, Nano Lett. 2017, 17, 3844; X. Zhu, M. Du, J. Feng, H. Wang, Z. Xu, L. Wang, S. Zuo, C. Wang, Z. Wang, C. Zhang, Angew. Chem. Int. Ed. 2021, 60, 4238; X. Zheng, B. Chen, J. Dai, Y Fang, Y Bai, Y Lin, H. Wei, X. C. Zeng, J. Huang, Nat. Energy 2017, 2, 1.
[22]Q. Dong, Y Fang, Y Shao, P. Mulligan, J. Qiu, L. Cao, J. Huang, Science 2015, 347, 967.
[23]R. Brenes, C. Eames, V. Bulovid, M. S. Islam, S. D. Stranks, Adv. Mater. 2018, 30, 1706208; Y Jiang, X. Wang, A. Pan, Adv. Mater. 2019, 31, 1806671.
D. Li, Y Meng, Y Zhang, P. Xie, Z. Zeng, Wei Wang, Z. Lai, Weijun Wang, S.-W. Tsang, F. Wang, C. Liu, C. Lan, S. Yip, J. C. Ho, Adv. Funct. Mater, 2023, 2302866.

What is claimed is:

1. A high-quality perovskite microwire (MW) parallel array, comprising:
perovskite; and
oxygen-filled surface bromine vacancies;
wherein the perovskite comprises specifically terminated surfaces.

2. The high-quality perovskite MW parallel array of claim 1, wherein
(i) the perovskite comprises an inorganic material; or
(ii) the perovskite comprises an inorganic material and an organic material.

3. The high-quality perovskite MW parallel array of claim 1, wherein the perovskite is CsPbBr₃ and has specifically terminated (100) surfaces.

4. A method of making the high-quality perovskite MW parallel array of claim 1, comprising:
(a) providing a substrate;
(b) growing perovskite MW parallel arrays on the substrate; and
(c) passivating with oxygen.

5. The method of claim 5, wherein growing comprises a chemical vapor deposition (CVD) step.

6. The method of claim 5, wherein passivating with oxygen comprises storing the perovskite MW parallel arrays in an ambient environment for about 3000 hours or more.

7. The method of claim 5, wherein the substrate comprises muscovite mica.

8. A product comprising the high-quality perovskite MW parallel array of claim 1, wherein the product is selected from the group consisting of a photodetector, a sensor, a LED, a synapse, and a memory device.

9. A photodetector, comprising:
a high-quality perovskite MW parallel array; and
one or more electrodes;
wherein the high-quality perovskite MW parallel array comprises:
perovskite; and
oxygen-filled surface bromine vacancies;
wherein the perovskite has specifically terminated surfaces.

10. The photodetector of claim 9, wherein
(i) the perovskite comprises an inorganic material; or
(ii) the perovskite comprises an inorganic material and an organic material.

11. The photodetector of claim 9, wherein the perovskite is CsPbBr₃ and has specifically terminated (100) surfaces.

12. The photodetector of claim 9, further comprising an on/off ratio of about 3×10⁴ to about 5×10⁴.

13. The photodetector of claim 9, further comprising a responsivity value of about 215 A W⁻¹ to about 263 A W⁻¹.

14. The photodetector of claim 9, further comprising a detectivity value of about 0.86×10¹² Jones to about 1.06×10¹² Jones.

15. The photodetector of claim 9, further comprising a rise time of about 94 μs to about 200 μs.

16. The photodetector of claim 9, further comprising a recovery time of less than about 300 μs.

17. The photodetector of claim 9, further comprising an ambient stability time of about 3000 hours or greater.

18. The photodetector of claim 9, further comprising:
(i) an on/off ratio of about 5×10⁴;
(ii) a responsivity of about 263 A W⁻¹;
(iii) a detectivity of about 1.06×10¹² Jones;
(iv) a rise time of about 94 μs;
(v) a recovery time of about 136 μs; and
(vi) an ambient stability time of about 3000 hours.

19. A method of making the photodetector of claim 9, comprising:
(a) providing a substrate;
(b) growing perovskite MW parallel arrays on the substrate;
(c) passivating the perovskite MW parallel arrays with oxygen; and
(d) depositing one or more electrodes onto the substrate.

20. The method of claim 19, wherein growing comprises a chemical vapor deposition (CVD) step.
